(19) United States
(12) Patent Application Publication
(10) Pub. No.: US 2006/0163201 A1
(43) Pub. Date: Jul. 27, 2006

(54) PLASMA PROCESSING SYSTEM AND PLASMA TREATMENT PROCESS

(75) Inventors: James Getty, Vacaville, CA (US); Louis Fierro, Clearwater, FL (US)

Correspondence Address: WOOD, HERRON & EVANS, LLP (NORDSON), 2700 CAREW TOWER, 441 VINE STREET, CINCINNATI, OH, 45202, US

(73) Assignee: Nordson Corporation, Westlake, OH (US)

(21) Appl. No.: 11/278,483

(22) Filed: Apr. 3, 2006

Related U.S. Application Data
(63) Continuation of application No. PCT/US04/32973, filed on Oct. 6, 2004.
(60) Provisional application No. 60/515,039, filed on Oct. 28, 2003.

(51) Int. Cl. C23F 1/00; H05H 1/24; C23C 16/00

(52) U.S. Cl. 216/67; 427/569; 118/723 E; 156/345.43

(57) ABSTRACT

A plasma treatment system for treating multiple substrates with a plasma. The treatment chamber of the plasma treatment system includes at least one pair of electrodes, typically vertically oriented, between which a substrate is positioned for plasma treatment. Each electrode includes a perforated panel that permits horizontal process gas and plasma flow, which improves plasma uniformity. A process recipe is defined that is effective for removing thin polymer areas, such as flash or chad, attached to and projecting from a polymer substrate.

### CROSS-REFERENCE TO RELATED APPLICATIONS

This application is a continuation of Serial No. PCT/US2004/032973 filed on Oct. 6, 2004 which claims the benefit of U.S. Provisional Application No. 60/515,039 filed on Oct. 28, 2003, and the disclosures of which are hereby incorporated by reference in their entirety herein.

### FIELD OF THE INVENTION

The invention relates generally to plasma processing, and more particularly to a plasma treatment system configured to treat substrates.

### BACKGROUND OF THE INVENTION

Plasma treatment is commonly used to modify the surface properties of substrates used in applications relating to integrated circuits, electronic packages, and printed circuit boards. In particular, plasma treatment is used in electronics packaging, for example, to increase surface activation and/or surface cleanliness for eliminating delamination and bond failures, improving wire bond strength, ensuring void free underfilling of chips on circuit boards, removing oxides, enhancing die attach, and improving adhesion for die encapsulation.

Typically, one or more substrates are placed in a plasma treatment system and a surface of each substrate is exposed to generated plasma species. The outermost surface layers of atoms are removed by physical sputtering, chemically-assisted sputtering, and chemical reactions promoted by the plasma. The physical or chemical action may be used to condition the surface to improve properties such as adhesion, to selectively remove an extraneous surface layer, or to clean undesired contaminants from the substrate's surface.

Conventional batch plasma treatment systems exist in which both sides of multiple large panels of material are plasma treated. Each of the panels is positioned between a pair of planar electrodes, which are energized with a suitable atmosphere present in the treatment chamber of the treatment system to generate a plasma. In such plasma treatment systems, one factor affecting the degree of etch uniformity is the spatial uniformity of the plasma density adjacent to the substrate, which is dictated by the design of the electrodes used to create the plasma. Solid planar electrodes produce a uniform plasma but cannot provide adequate gas flow so that the etch rate may be unacceptably low. Therefore, conventional solid electrodes in batch treatment chambers have failed to provide adequate process uniformity across opposite sides of large planar substrates. The plasma density must be precisely and accurately controlled at all spatial positions surrounding both sides of each substrate to provide etch uniformity on both surfaces.

There is thus a need for a plasma treatment system that can uniformly plasma treat both sides of planar substrates each characterized by a large surface area.

### SUMMARY OF THE INVENTION

The invention addresses these and other problems by providing a plasma treatment system that includes a vacuum chamber with a processing space, a vacuum port for evacuating the processing space, and a gas port for introducing a process gas into the processing space. The system further includes a plasma excitation source capable of generating a plasma from the process gas in the processing space and a plurality of electrodes electrically coupled with the plasma excitation source. The electrodes are arranged to define a corresponding plurality of processing regions therebetween in the processing space for treating substrates with the plasma. Each electrode includes at least one perforated panel that operates to transfer the process gas and the plasma through the electrode.

The invention contemplates that the plasma treatment system may be used to plasma treat substrates composed of a wide range of materials, including but not limited to ceramics, metals, and polymers. The plasma treatment may consist of etching, cleaning, surface activation, and any other type of surface modification apparent to a person of ordinary skill in the art. For example, the plasma treatment may be used to etch a substrate as part of a standard lithography and etch process for forming features in the substrate.

In another embodiment of the invention, a method of plasma treating a substrate includes positioning the substrate between a pair of electrodes situated inside a treatment chamber, introducing a process gas into the treatment chamber, and energizing the pair of electrodes to generate a plasma from the process gas within the treatment chamber. The method further includes directing a flow of the process gas and the plasma through a porous portion of each of the electrodes from a location outside the processing region to a pair of locations inside the processing region each defined between one of the electrodes and the substrate.

In yet another embodiment of the invention, a method is provided for removing relatively thin attached areas of polymer, such as chad or flash, projecting from a polymer substrate. The method includes supplying a process gas to a treatment chamber holding the polymer substrate characterized by a gas mixture including oxygen and nitrogen trifluoride in an amount of less than or equal to about 10 percent by volume of the gas mixture, transferring RF power to the process gas to generate a plasma, and exposing the polymer substrate to the plasma for a time effective to remove the thin attached polymer areas. In specific embodiments, RF power is transferred to the process gas in a range of about 4000 watts to about 8000 watts at 40 kHz. In other specific embodiments, the polymer substrate is heated to a process temperature in the range of about 30° C. to about 90° C. Preferably, the gas mixture includes about 5 percent by volume to about 10 percent by volume of nitrogen trifluoride and the balance of the gas mixture is oxygen.

These and other objects and advantages of the present invention shall become more apparent from the accompanying drawings and description thereof.

### BRIEF DESCRIPTION OF THE FIGURES

The accompanying drawings, which are incorporated in and constitute a part of this specification, illustrate embodiments of the invention and, together with a general description of the invention given above, and the detailed description given below, serve to explain the principles of the invention.

FIG. 1 is a perspective view of a plasma treatment system in accordance with an embodiment of the invention;

FIG. 2 is a cross-sectional view of the plasma treatment system of FIG. 1;

FIG. 2A is a cross-sectional view taken generally along lines 2A-2A of FIG. 2;

FIG. 3 is a diagrammatic end view of a portion of the plasma treatment system showing the relationship between the electrodes of the invention and a batch of substrates;

FIG. 4 is a side view of an alternative embodiment of an electrode in accordance with the invention;

FIG. 5 is a perspective view of a substrate-holding rack for use with the plasma treatment system of FIG. 1 in accordance with an alternative embodiment of the invention;

FIG. 6 is an end view of the substrate holders of the rack of FIG. 5;

FIG. 7 is a side view of the rack of FIG. 5 in which one of the substrate holders is visible; and

FIGS. 8A-D are end views of one of the substrate holders, shown in FIG. 5, illustrating a procedure for loading substrates into the rack of FIG. 5.

### DETAILED DESCRIPTION OF THE PREFERRED EMBODIMENTS

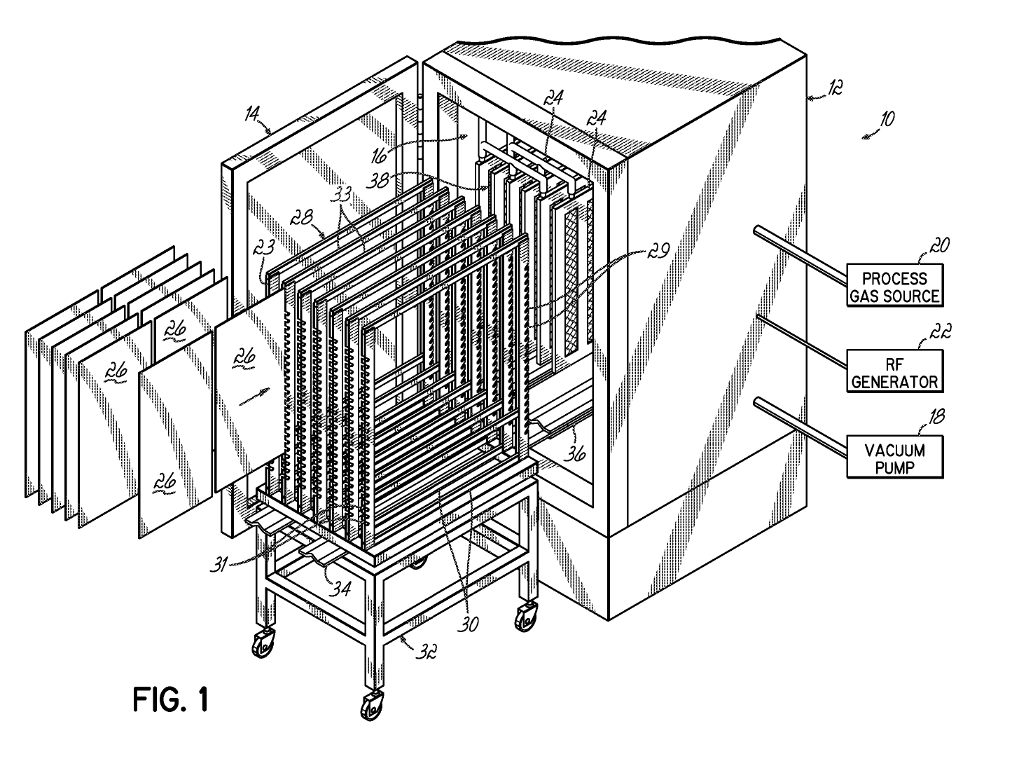

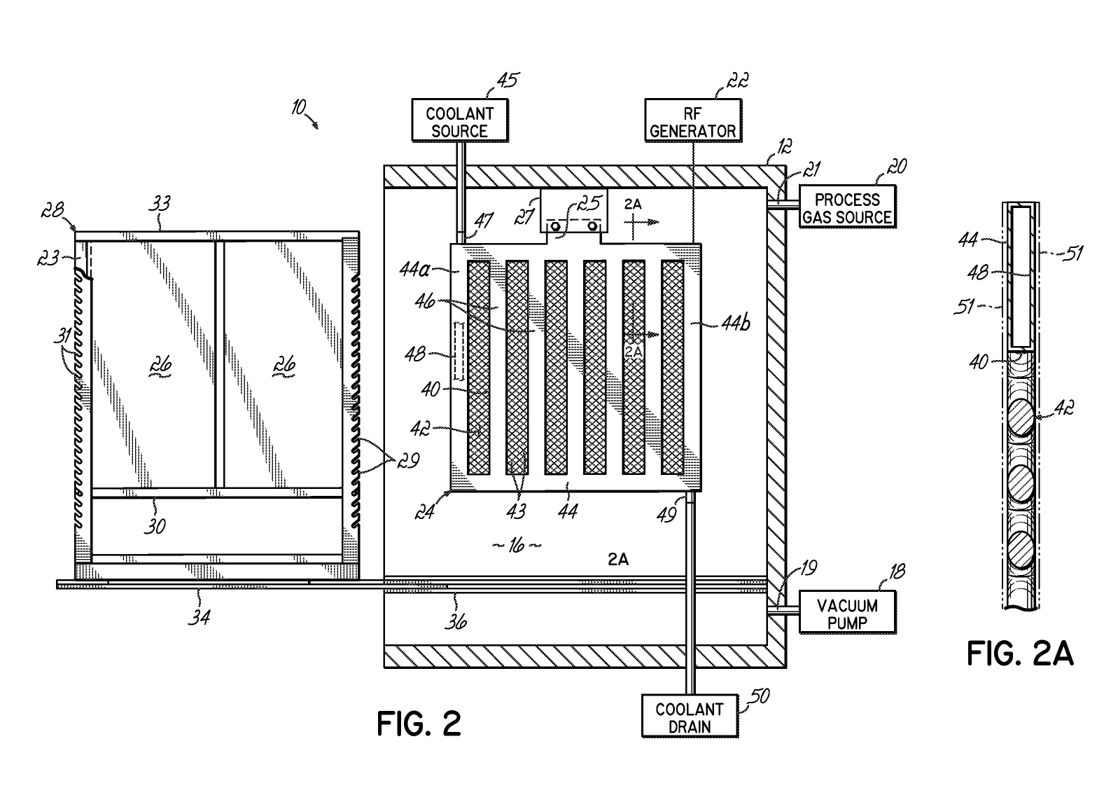

With reference to FIGS. 1 and 2, a plasma treatment system 10 includes a treatment chamber 12 with a chamber door 14 selectively positionable between an open position that affords access to an evacuable processing space 16 enclosed by the surrounding walls of the treatment chamber 12 and a closed position in which the processing space 16 is sealed fluid-tight from the surrounding ambient environment. The chamber door 14 may carry a latch that engages another portion of the treatment chamber 12 when the chamber door 14 is in the closed position and secures the chamber door 14 in a sealed engagement. A sealing member (not shown) surrounds the periphery of either the chamber door 14 or the periphery of the portion of the treatment chamber 12 about the access opening to the processing space 16 defined when the chamber door 14 is in the open position. The treatment chamber 12 is formed of an electrically conductive material suitable for high-vacuum applications, such as an aluminum alloy or stainless steel, and is electrically grounded.

The treatment chamber 12 is evacuated through a vacuum port 19 by vacuum pump 18 that may comprise one or more vacuum pumps apparent to a person of ordinary skill in the art of vacuum technology. Process gas is admitted to the processing space 16 from a process gas source 20 through an inlet gas port 21 extending through one wall of the treatment chamber 12 at a predetermined flow rate, such as about 2 to about 4 standard liters per minute (slm). The process gas flow is typically metered by a mass flow controller (not shown). The flow rate of gas provided by the mass flow controller and the pumping rate of vacuum pump 18 are adjusted to provide a processing pressure suitable for plasma generation so that subsequent plasma processing may be sustained.

The processing space 16 is evacuated simultaneously with the introduction of the process gas so that fresh gases are continuously exchanged within the processing space 16. During a plasma treatment process, contaminant species sputtered from a planar substrate 26 and spent process gas will be evacuated from processing space 16 by the vacuum pump 18 along with a portion of the flowing stream of process gas. Operating pressures during plasma treatments within the treatment chamber 12 are typically about 150 mTorr to 300 mTorr.

The planar substrates 26 described herein may have features projecting therefrom or embossed therein and are not limited to feature-less planar panels. In addition, the planar substrates 26 are not limited to being rectangular in area but, instead, may have other geometrical shapes.

With continued reference to FIGS. 1 and 2, a plasma excitation source like radio-frequency (RF) generator 22 is electrically coupled with, and transfers electrical power to, a plurality of electrodes 24 for ionizing and dissociating the process gas confined within processing space 16 to initiate and sustain a plasma. The treatment chamber 12 serves as an unpowered, ground electrode. The RF generator 22 includes an impedance matching device and an RF power supply operating at a frequency between about 40 kHz and about 13.56 MHz, preferably about 40 kHz although other frequencies may be used, and a power between about 4000 watts and about 8000 watts at 40 kHz or 300 watts to 2500 watts at 13.56 MHz. However, different treatment chamber designs may permit different bias powers or may permit use of a direct current (DC) power supply. A controller (not shown) is coupled to the various components of the plasma treatment system 10 to facilitate control of the etch process.

The RF power supply of RF generator 22 may be a dual output power supply such that alternating electrodes 24 are bussed together and provide power at 180° out of phase with the remaining electrodes 24, which are also bussed together. This arrangement improves on certain conventional designs in which alternating electrodes were powered and the remaining electrodes were grounded, which produced higher etch rates on the side of the planar substrate adjacent to the powered electrode. As both electrodes 24 are powered in accordance with the invention, the etch rate is similar on the opposite sides of one or more planar substrates 26 positioned between a pair of the electrodes 24.

With continued reference to FIGS. 1 and 2, a rack 28 is provided that supports planar substrates 26 inside the treatment chamber 12 during plasma processing. The rack 28 has position bars 30 that are vertically adjustable among multiple notches 29, 31 along opposite vertical edges of each of the individual substrate holders 33 to define slots 23 for accommodating planar substrates 26 of differing vertical dimensions. Each planar substrate 26 is insertable into one of the slots 23 in the rack 28. The rack 28 is carried by a wheeled cart 32 when outside of the treatment chamber 12 for ease of movement.

The wheeled cart 32 includes a track 34 along which the rack 28 is horizontally movable and that is at approximately the same vertical height as a corresponding track 36 inside the treatment chamber 12. After a group or batch of planar substrates 26 is loaded into the rack 28, the chamber door 14 is opened and the rack 28 is positioned so that tracks 34 and 36 are registered. Rack 28 is transferred from the track 34 of the wheeled cart 32 to the track 36 inside treatment chamber 12 and the chamber door 14 is closed to provide a sealed environment ready for evacuation by vacuum pump 18.

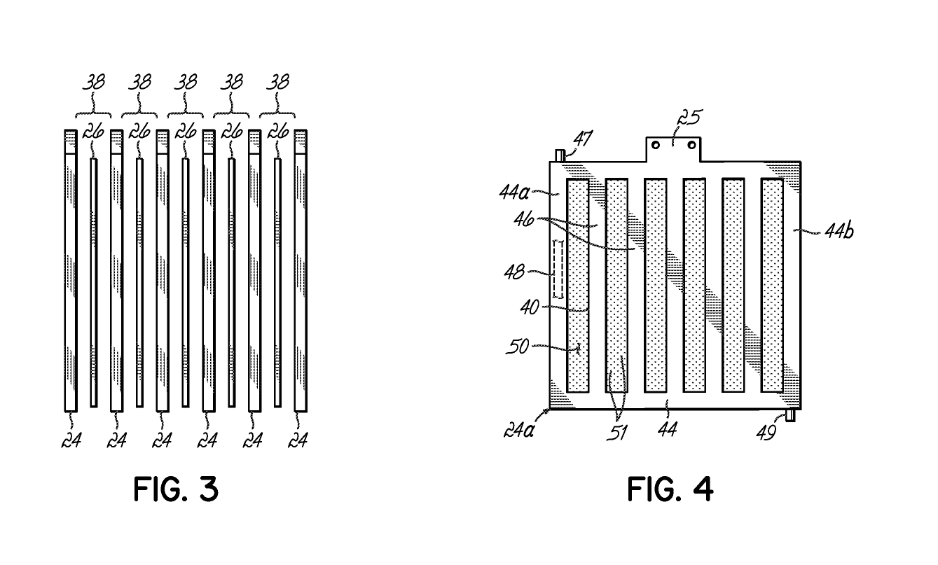

With reference to FIGS. 1-3, the electrodes 24 are vertically suspended by a corresponding tang 25 from the ceiling of the treatment chamber 12 by a support 27. Each of the electrodes 24 is electrically coupled with the RF generator 22 for receiving electrical power sufficient to generate a plasma. The electrodes 24 are horizontally spaced such that a processing region 38 is defined between each adjacent pair of electrodes 24. Each region 38 receives a planar substrate 26 for plasma treatment of both opposite sides of the substrate 26 as a plasma is present between each flanking electrode 24 and one side of the substrate 26. Positioned in the region 38 between each adjacent pair of electrodes 24 is one of multiple planar substrates 26 oriented generally parallel to the plane of each flanking electrode 24. The planar substrates 26 are floating electrically relative to the electrodes 24 and the treatment chamber 12.

Each electrode 24 includes at least one perforated panel 42 of, for example, metallic mesh filling an otherwise open space 40. Each perforated panel 42 is characterized by a porosity represented by a ratio of the total cross-sectional area of passageways or apertures 43 in the perforated panel 42 to the total area of the perforated panel 42. In a specific embodiment of the invention, each electrode 24 includes an annular peripheral frame 44 with a plurality of vertical cross members 46 extending from one horizontal side of the frame 44 to the opposite horizontal side of the frame 44. One perforated panel 42 is positioned in the space defined between each pair of cross members 46 and in the spaces between the cross members 46 at the extrema (i.e., frontmost and rearmost) of the set of cross members 46 and the corresponding opposite vertical sides 44a, 44b of the frame 44.

Each perforated panel 42 defines a flow path for process gas and plasma species into and between the regions 38 between adjacent electrodes 24. Typically, the ratio of the collective cross-sectional area of the apertures 43 in each perforated panel 42 to the total area of each perforated panel 42 (i.e., the open area ratio) is less than about 20%. Preferably, the open area ratio is adjusted by varying the panel mesh size such that electrode 24 resembles a solid electrode sufficient to simulate a solid electrode and to provide an adequate etch rate without overly restricting gas flow. The mesh size for perforated panel 42 is depicted diagrammatically in the Figures and may be exaggerated (i.e., not to scale) for purposes of illustration.

The mesh size of the individual perforated panels 42 may vary depending upon the position within the electrode 24. For example, the mesh size may be greater for panels 42 near the center of the electrode 24 as compared with panels 42 adjacent to the sides 44a, 44b of the electrode 24. This permits the gas conductance to different portions of the region 38 between adjacent electrodes 24 to be adjusted across the width of the electrodes 24 and may be useful for equalizing the etch rate across the width of the flanked substrate 26.

The perforated panel 42 is coupled thermally and electrically with the frame 44 and cross members 46 for efficient heat and current transfer. Preferably, the perforated panel 42 has the same thickness as the frame 44 and cross members 46 so that the electrode 24 has a uniform thickness across its area, as is shown in FIG. 2A. In certain embodiments, the perforated panel 42 may be thinner than the frame 44 and cross members 46, in which instance the panel 42 is positioned to be coplanar with the midplane of the frame 44 and cross members 46.

The electrodes 24 have a flanking relationship defined as a side-by-side, spaced-apart relationship in which adjacent electrodes 24 are generally parallel. The invention contemplates that, in various alternative embodiments of the invention, the electrodes 24 may be oriented vertically, horizontally or at any angle therebetween.

With continued reference to FIGS. 1, 2, 2A and 3, the number of electrodes 24 scales with the number of planar substrates 26 and the dimensions of the treatment chamber 12. If the number of substrates 26 to be treated is represented by the number (n), the number of electrodes 24 will be equal to (n+1) as each substrate 26 is flanked by a pair of electrodes 24. The separation between adjacent electrodes 24 can range from about six (6) cm to about one (1) cm and is contingent among other variables upon the thickness of the substrates 26.

The temperature of the electrodes 24 is controlled by circulating distilled water or another suitable heat-exchange liquid through a serpentine passageway 48 winding inside the tubular frame 44 and cross members 46. To that end, the heat-exchange liquid is supplied from a source 45 external to the treatment chamber 12 to an inlet port 47 of the serpentine tubular passageway 48 of each electrode 24 to an outlet port 49 of a coolant drain 50. The heat-exchange liquid can be used to heat or cool the electrodes 24, depending on the desired effect, by regulating the flow rate and temperature of the liquid. Because heat is transferred from the electrodes 24 to the substrates 26, regulation of the temperature of the electrodes 24 may also be used to beneficially regulate the temperature of the substrates 26 during plasma treatment. In certain embodiments of the invention, the circulation of the heat-exchange liquid may remove excess heat from the electrodes 24.

In one aspect of the invention, the rectangular dimensions or area of the electrode 24 is greater than the rectangular dimensions or area of the substrates 26 being plasma treated. In certain embodiments of the invention, the length and width (i.e., outer dimensions) of the rectangular frame 44 of each electrode 24 is at least about one inch (1″) larger than the substrate 26. Adjusting the relative areas of the electrode 24 and substrate 26 aids in ensuring that the plasma treatment about the substrate periphery is similar to the plasma treatment near the substrate center. The electrodes 24 all have equal areas for the opposite rectangular surfaces confronting the flanking substrates 26.

The electrodes 24 are formed from a metal having relatively high electrical and thermal conductivities, such as aluminum. The side surface of the electrode 24 facing the substrate 26 may be coated by a process such as anodization or chemical vapor deposition with an optional layer 51 of a non-metal. The optional non-metal layer 51 is believed to improve the edge-to-center plasma uniformity. The non-metal layer 51 coating the electrically-conductive core of the electrode 24 may have a thickness ranging from about 10 microns (μm) to about 300 microns. Exemplary coating materials include, but are not limited to, refractory materials such as aluminum oxide and silicon. In certain embodiments, the non-metal layer 51 may be applied only to the frame 44 as the edges of the electrode 24 are believed to induce local variations in plasma density, which are significantly reduced or eliminated by the presence of the non-metal layer 51. In certain embodiments of the invention, the non-metal layer 51 may be applied as a laminate to the electrode 24. Adding the non-metal layer 51 may permit the electrode 24 to have an area confronting the substrate 26 that is substantially equal to the substrate area while improving edge-to-center process uniformity and plasma uniformity.

References herein to terms such as “vertical”, “horizontal”, etc. are made by way of example, and not by way of limitation, to establish a frame of reference. It is understood various other frames of reference may be employed without departing from the spirit and scope of the invention. Although the electrodes 24 are referred to as being vertically oriented, the invention contemplates that the electrodes 24 may be oriented horizontally without departing from the spirit and scope of the invention.

In use and with reference to FIGS. 1, 2, 2A and 3, the planar substrates 26 are loaded onto the rack 28 and transferred into the treatment chamber 12, which is sealed by closing chamber door 14. The processing space 16 is evacuated by vacuum pump 18 to a chamber pressure lower than the system operating pressure. A flow of process gas is introduced to raise the chamber pressure to a suitable operating pressure, typically in the range of about 150 mTorr to about 300 mTorr, while actively evacuating the processing space 16 with vacuum pump 18. The RF generator 22 is energized for supplying electrical power to the electrodes 24, which generates a plasma in the processing space 16 and, in particular, in the region 38 between each pair of adjacent electrodes 24 in which one of the planar substrates 26 is disposed. A coolant flow is initiated through the passageway 48 inside the tubular frame 44 and cross members 46 of each electrode 24 for regulating the electrode temperature.

The process gas and plasma species flow and diffuse through the perforated panel 42 into and between the regions 38 defined between adjacent electrodes 24. Process gas and plasma can likewise flow into regions 38 through the gaps defined about the peripheral edges of the confronting electrodes 24. The presence of the perforated panels 42 promotes the transfer of process gas and plasma species between the regions 38 and from the processing space into the regions 38 associated with the endmost electrodes 24. The substrates 26 are exposed to the plasma for a duration sufficient for treating (i.e., etching, cleaning, patterning, modifying, activating, etc.) the exposed opposite surfaces of the planar substrates 26. After the treatment is completed, the chamber door 14 is opened, the rack 28 is removed from the treatment chamber 12, and the substrates 26 are offloaded.

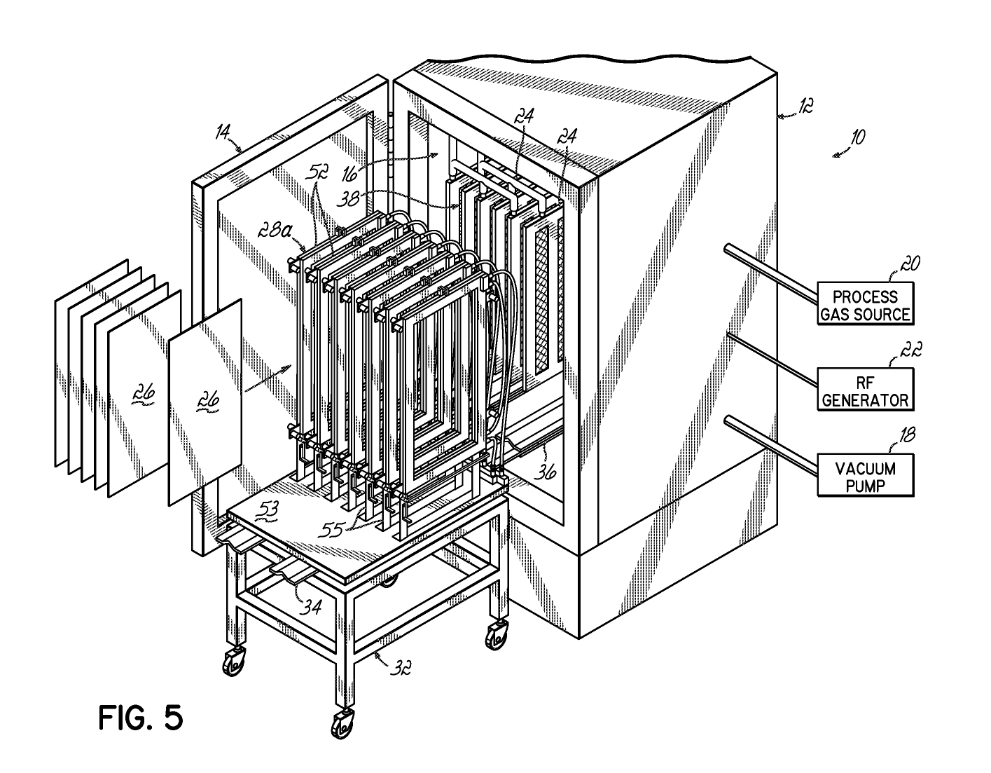

With reference to FIG. 4 in which like reference numerals refer to like features in FIGS. 1-3 and in accordance with an alternative embodiment of the invention, an electrode 24a includes a perforated bar or panel 50 positioned in each of a plurality of openings defined between cross members 46 and the frame 44. The panels 50 may be welded to the portions of the frame 44 and cross members 46 to define an integral structure. Each perforated panel 50 is perforated with passageways or apertures 51 so that process gas cross-flow can occur for improving plasma uniformity. The open area of each panel 50 is less than about 20% and may be, for example, less than about 1%. Preferably, each perforated panel 50 has the same thickness as the frame 44 and cross members 46 so that the electrode 24a more resembles a solid electrode. The open area of the individual panels 50 may vary depending upon the position within the electrode 24a between side edges 44a, 44b. For example, the open area may be greater for panels 50 near the center of the electrode 24a as compared with panels 50 adjacent to the side edges 44a, 44b of the electrode 24a. This permits the gas conductance to different portions of the region 38 between adjacent electrodes 24a to be adjusted across the width of the electrodes 24a and may be useful for equalizing the etch rate across the width of the flanked substrate 26.

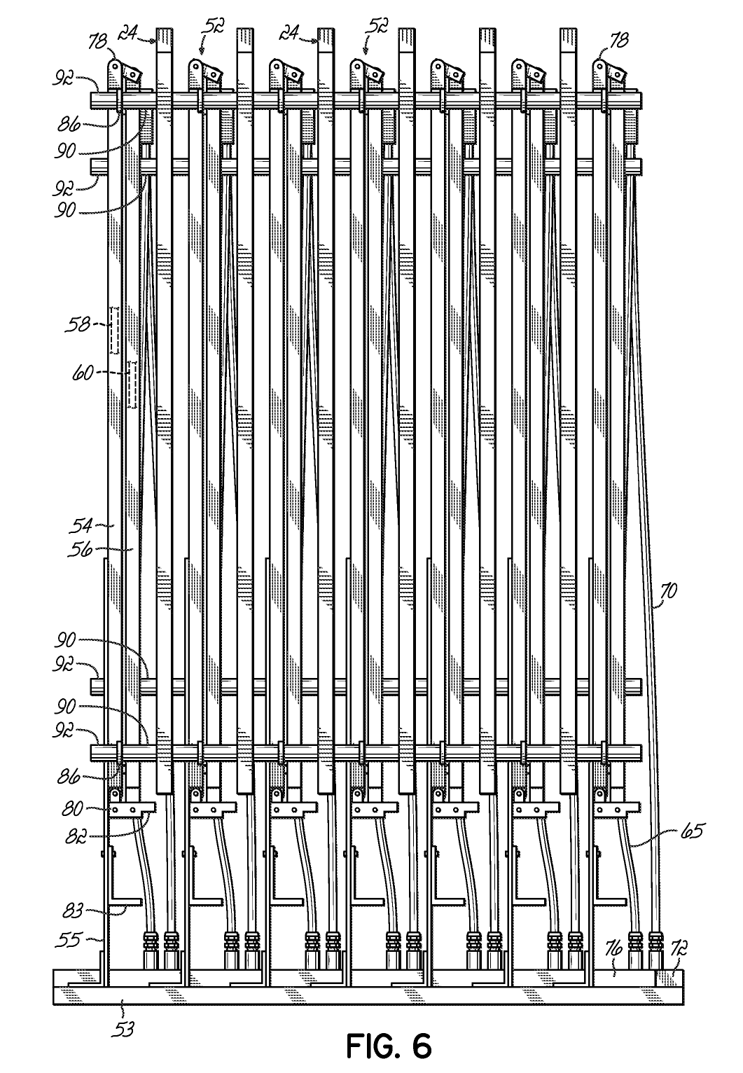

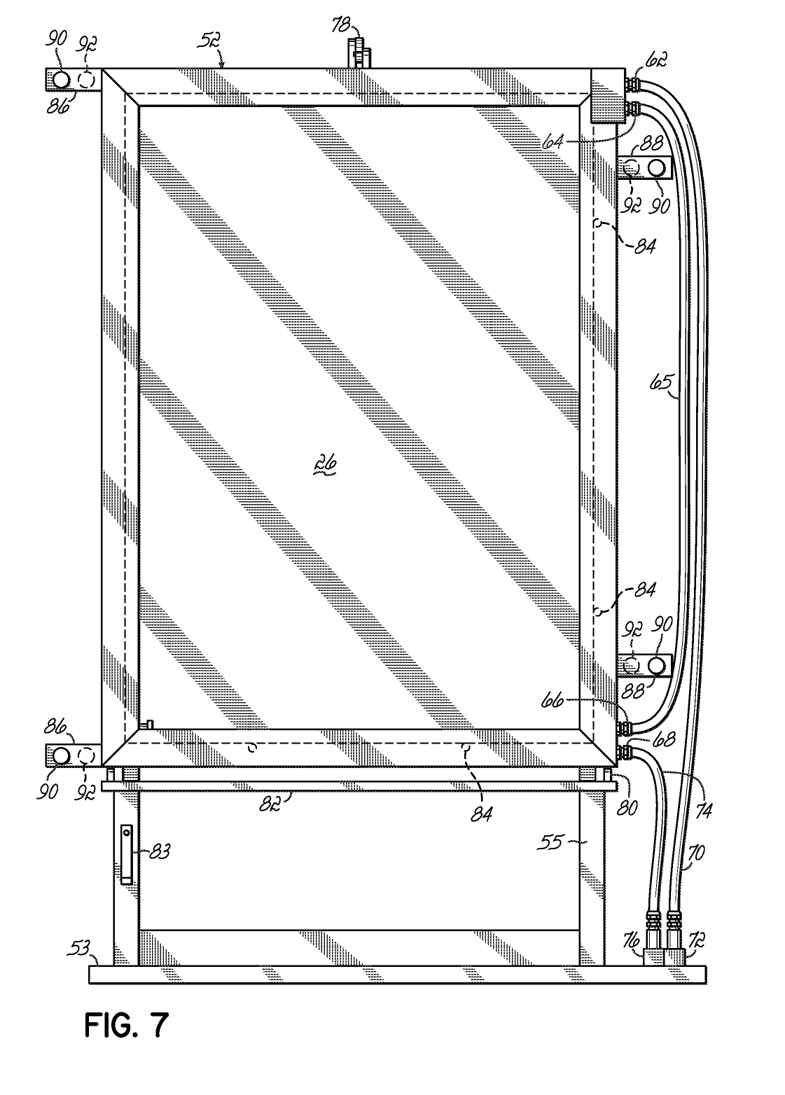

With reference to FIGS. 5-7 and 8A, a rack 28a for use in plasma treatment system 10 includes multiple substrate holders 52 each configured to hold one or more substrates 26. Rack 28a, which is carried on wheeled cart 32 when outside of the treatment chamber 12, is inserted into treatment chamber 12 like rack 28 (FIG. 1) for treating the held substrates 26. In contrast to rack 28, rack 28a includes active water cooling and substrate clamping for providing an efficient heat transfer path to remove heat from the substrates 26 during plasma treatment. When inserted into the treatment chamber 12 by movement along track 34, each of the substrate holders 52 is positioned between a pair of the electrodes 24. The substrate holders 52 are arranged parallel to one another and each substrate holder 52 is supported on a common base 53 by a support structure 55.

Each of the individual substrate holders 52 includes a pair of hollow frames 54, 56 each of which has a fluid passageway 58, 60, respectively, extending about its periphery and through which a heat-exchange liquid like distilled water may be circulated. The circulated heat-exchange liquid cools the substrate holder 52 and, by conduction, removes heat from the substrate 26 for reducing the temperature of the substrate 26 during plasma treatment. The frames 54, 56 define a central rectangular window across which the substrate 26 is exposed to the plasma inside of the treatment chamber 12. The frames 54, 56 may be formed from any material having good thermal conductivity, such as aluminum.

The heat-exchange liquid is transferred through the fluid passageway 58 in frame 54 between a liquid inlet 62 and a liquid outlet 64. The liquid outlet 64 of frame 54 is coupled by a conduit 65 with a liquid inlet 66 of the fluid passageway 60 in frame 56. Fluid passageway 60 includes a liquid outlet 68 for draining the cooling liquid from the substrate holder 52. As a result, frames 54 and 56 share the circulated heat-exchange liquid. The heat-exchange liquid is supplied to the liquid inlet 62 of frame 54 by a supply line 70 extending from a coolant manifold 72 and returned by a drain line 74 to a drain 76. Each of the other substrate holders 52 is configured with the same type of cooling arrangement and shares the coolant manifold 72 and drain 76. Liquid inlet 66, supply line 70, and drain line 74 may be, for example, lengths of flexible Teflon® tubing.

The flow of coolant liquid to the substrate holders 52 may be controlled by measuring the temperature of the substrates 26. If the substrate temperature exceeds a target temperature, a flow of the coolant liquid may be established for cooling the substrates 26.

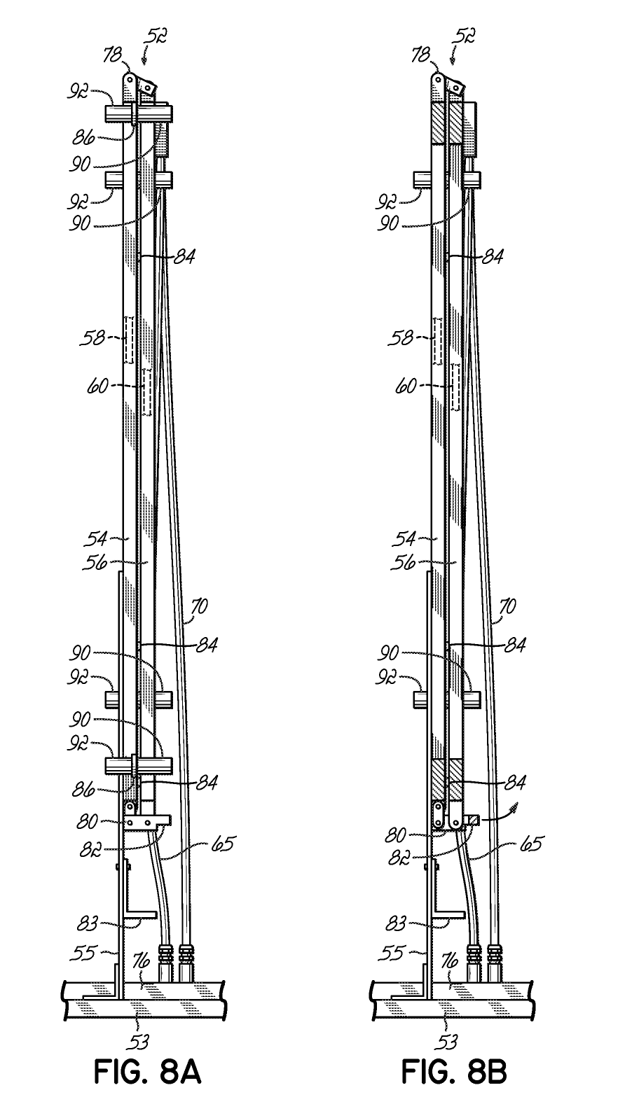

The hollow frames 54, 56 have a clamping relationship with the outer perimeter of the substrate 26 that provides an efficient heat transfer path. The upper ends of the hollow frames 54, 56 are coupled together by a hinge 78, which preferably has a three-point design so that the hollow frames 54, 56 can move laterally and vertically relative to each other. A cam action opener 80, which is actuated by an opener bar 82 (FIG. 7), connects the lower ends of the hollow frames 54, 56. The opener bar 82 moves the opener 80 from a first generally L-shaped condition in which the frames 54, 56 are unspaced to a second condition in which the frames 54, 56 are separated and vertically spaced apart from one another. When the opener bar 82 is operated to actuate opener 80, a support stop 83 is movable for contacting the opener 80, which maintains the frames 54, 56 stationary and in the opened position for inserting a substrate 26 between the frames 54, 56. The support stop 83 is pivotally coupled with the support structure 55.

The frame 54 of each substrate holder 52 includes multiple locators 84 that cooperate to locate the substrate 26 held by the hollow frames 54, 56. Two locators 84 (FIG. 7) contact a bottom edge of the substrate 26 and two locators 84 contact one side edge of the substrate 26, although the invention is not so limited. Frame 54 includes two arms 86 extending toward the front of the treatment chamber 12 and two arms 88 extending toward the rear of the treatment chamber 12. Each of the arms 86, 88 carries an alignment post 90 that projects outwardly in an opposite direction from another alignment post 92. The alignment post 90 on arms 86, 88 contacts the vertical electrode 24 flanking one side of the substrate holder 52 at four points and the alignment post 92 on arms 86, 88 contacts the vertical electrode 24 flanking the opposite side of the substrate holder 52 at four points. The contact operates to ensure parallelism between the substrate 26 and the flanking pair of electrodes 24. More specifically, the alignment posts 90, 92 cooperate to position the substrate 26 at a mid-plane location between the flanking electrodes 24 and in a plane bearing a vertical relationship with a vertical plane defined by each of these flanking electrodes 24. To that end, each of the alignment posts 90, 92 projects an equal distance from the substrate holder 52.

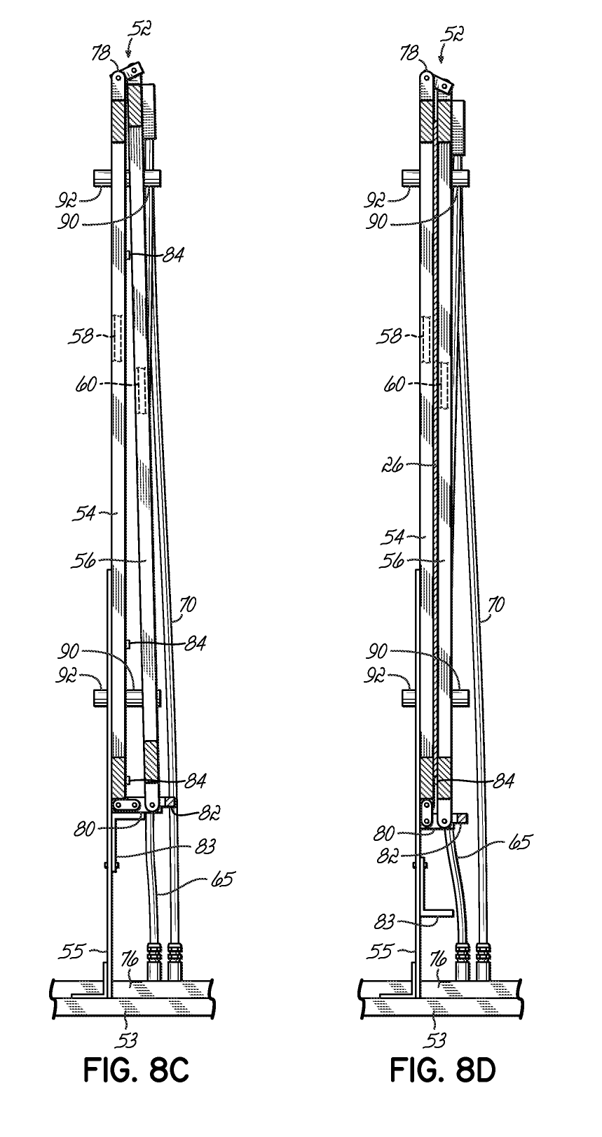

In use and with reference to FIGS. 8A-D in which like reference numerals refer to like features in FIGS. 5-7, a procedure for loading substrates 26 into rack 28a will be described. Initially, the rack 28a is outside of the treatment chamber 12 and supported on wheeled cart 32 with each of the substrate holders 52 in a closed position, as shown in FIG. 8A. In this loading position, the opener bar 82 is used to actuate the cam action opener 80, which moves frame 56 laterally and vertically relative to frame 54, as shown in FIG. 8B, and provides the opened position. The support stop 83 is pivoted into position so that the frames 54, 56 are held in the opened position to provide a gap for receiving a substrate 26, as shown in FIG. 8C.

After the substrate 26 is positioned between the frames 54, 56, the support stop 83 is pivoted back to its initial position, which allows the frames 54, 56 to close on the substrate 26 so that the perimeter of the substrate 26 is pinched between the frames 54, 56 with contact sufficient to define a good heat transfer path. The weight of the frames 54, 56 maintains the frames 54, 56 in the closed position. A substrate 26 is loaded into each of the substrate holders 52 and the rack 28a is positioned at a treatment position inside the treatment chamber 12 for plasma treating the substrates 26. The alignment posts 90, 92 contact the adjacent electrodes 24 so that each substrate 26 is in a plane parallel to the planes containing each of the adjacent electrodes 24. A plasma generated in the treatment chamber 12 treats the surfaces of the substrates 26, as described above.

In one specific embodiment of the invention, the plasma treatment consists of a process that removes thin areas or tabs of polymer, such as flash or chad. These thin attached polymer areas may be created, for example, by past manufacturing steps that are attached to the planar substrates. The thin attached polymer areas are significantly thinner than the planar substrate 26. Typically, the attached thin polymer areas are less than about 5 microns thick. Therefore, the plasma treatment effectively and efficiently removes the thin attached polymer areas with a minimal impact on the thickness of the substrate 26. To that end, the plasma is sustained for a processing time or duration adequate to remove the thin attached polymer areas by an anisotropic etching process as ions and radicals in the plasma erode away the thin attached polymer areas while having little impact on the overall thickness of the substrate 26 and without changing any features (e.g., trenches and vias or metallization traces) present on the plasma treated surfaces.

In accordance with an embodiment of the invention, a processing recipe is provided for etching the thin polymer areas attached to the polymer planar substrate. A processing time in the range of about eight (8) minutes to about thirty (30) minutes suffices for removing such thin polymer areas of typical thickness (e.g., 5 microns) without detrimentally affecting the substrate. However, the exact processing time will depend upon multiple different variables including, but not limited to, the number of planar substrates being plasma treated and the precise thickness of the thin attached polymer areas.

The RF power supplied to the electrodes 24 (FIGS. 1-4) will be in the range of about 4000 watts to about 8000 watts at 40 kHz. The planar polymer substrates are maintained at a process temperature generally above ambient room temperature, such as a temperature in the range of about 30° C. to about 90° C., by heat transferred from the adjacent electrodes. Generally, etch rate increases with increasing process temperature, although uniformity may suffer as the process temperature increases above about 90° C. For certain polymers, the material forming the substrate may be temperature sensitive and limit suitable process temperatures.

Process gas is introduced into the process chamber with a flow rate of between two (2) slm and four (4) slm total to provide an operating pressure in the range of about 150 to about 300 mTorr. The process gas comprises a mixture of nitrogen trifluoride (NF₃) and oxygen (O₂), with nitrogen trifluoride comprising less than or equal to about 10 vol % of the gas mixture. Preferably, the process gas is a mixture of about 5 vol % to about 10 vol % of nitrogen trifluoride (NF₃) and the balance (90 vol % to 95 vol %) being oxygen (O₂), wherein the two components total 100 vol % of the process gas mixture. However, inert gases, such as argon (Ar), may be optionally added to the process gas mixture so long as the relative amounts of NF₂ and O₂ are kept constant. Radicals and ions of fluorine and oxygen present in the generated plasma remove material from the substrate surfaces and, in particular, remove the thin areas of polymer attached to and projecting from the substrate surfaces by forming volatile gaseous species that are evacuated from the processing chamber along with spent process gas.

Although the process recipe is generally applicable for removing thin attached polymer areas from planar substrates composed of a number of polymers, the process recipe is particularly applicable for removing thin areas of attached polymer from planar substrates composed of an ABF polymer. The use of nitrogen trifluoride improves over conventional polymer dry etch recipes that rely on carbon tetrafluoride or other fluoro-hydrocarbons because nitrogen tetrafluoride is less stable and dissociates more readily, which dramatically increases the radical yield in the plasma. A particular feature of the process recipe is that the source gas mixture used for etching lacks carbon. Thin attached polymer areas are also removed without resorting to wet chemical etching techniques. The process recipe of the invention is particularly applicable for removing unwanted thin attached polymer areas from the surfaces of embossed panels, such as double-sided printed circuit boards, because it is critical to start with a defect-free surface in subsequent processing steps, such as applying metallization in the embossed areas.

A residue may be present on the polymer substrate surfaces following the etching process that removes the thin attached polymer areas. In a second step of the process recipe, an atmosphere of a process gas appropriate for removing the residue may be provided for plasma generation without breaking vacuum and, preferably, without extinguishing the plasma. The radicals and ions of the process gas react with the debris to form volatile products that are evacuated from the plasma chamber. The process gas comprises a mixture of nitrogen trifluoride and oxygen, with nitrogen trifluoride comprising greater than or equal to about 90 vol % of the gas mixture. For example, in a situation for which the residue is silicon, the above-described gas mixture used for etching may be changed to about 90 vol % to about 95 vol % of NF₃ and the balance (5 vol % to 10 vol %) O₂. However, inert gases, such as Ar, may be optionally added to the process gas mixture so long as the relative amounts of NF₂ and O₂ are kept constant.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and methods, and illustrative examples shown and described. Accordingly, departures may be made from such details without departing from the spirit or scope of applicants' general inventive concept. The scope of the invention itself should only be defined by the appended claims, wherein we claim:

1. An apparatus for treating substrates with a plasma generated from a process gas, comprising:
a treatment chamber including a processing space, a vacuum port for evacuating said processing space, and a gas port for introducing a process gas into said processing space;
a plasma excitation source capable of generating a plasma from the process gas in said processing space; and
a plurality of electrodes electrically coupled with said plasma excitation source, said electrodes arranged to define a corresponding plurality of processing regions therebetween in the processing space for treating the substrates with the plasma, and each of said electrodes including at least one perforated panel that operates to transfer the process gas and the plasma through each of said electrodes.

2. The apparatus of claim 1 wherein said perforated panel defines a surface area having a plurality of apertures with an open area of less than 20% of said surface area.

3. The apparatus of claim 1 wherein at least one of said electrodes includes a plurality of perforated panels each of which defines a surface area having a plurality of apertures and an open area of less than 20% of said surface area.

4. The apparatus of claim 3 wherein at least two of said perforated panels have a different open area.

5. The apparatus of claim 1 wherein each of said electrodes includes a frame carrying said perforated panel and an internal passageway in said frame adapted to receive a flow of a coolant liquid.

6. The apparatus of claim 1 further comprising:
a plurality of substrate holders positioned inside said treatment chamber, each of said substrate holders positioned in one of said processing regions, and each of said substrate holders supporting at least one of the substrates.

7. The apparatus of claim 6 wherein each of said substrate holders includes first and second frames configured to apply a clamping force on an outer perimeter of the substrate, said first and second frames defining a window between said adjacent pair of said electrodes through said substrate holder for plasma exposure of the substrate.

8. The apparatus of claim 6 wherein each of said substrate holders includes a first plurality of alignment posts projecting toward one of said adjacent pair of said electrodes and a second plurality of alignment posts projecting toward the other of said adjacent pair of electrodes, said alignment posts dimensioned to position said substrate in a plane substantially parallel to a plane defined by each of the adjacent pair of electrodes.

9. The apparatus of claim 6 wherein said substrate holders and the substrates are transferable from a plurality of loading positions outside said treatment chamber to said processing regions inside said treatment chamber.

10. The apparatus of claim 1 wherein each of said electrodes comprises an electrically-conductive core and a non-metal layer coating said core.

11. The apparatus of claim 1 wherein each of said electrodes includes a frame surrounding said perforated panel, said frame and said perforated panel having a uniform thickness across an area of the electrode.

12. The apparatus of claim 1 wherein each of said electrodes includes a plurality of perforated panels each configured to transfer the process gas and the plasma through each of said electrodes.

13. The apparatus of claim 1 wherein said electrodes are arranged in substantially parallel planes having a flanking relationship to define said processing regions.

14. A method of plasma treating a substrate, comprising:
supporting the substrate in a processing region defined inside a treatment chamber between a pair of electrodes;
introducing a process gas into the treatment chamber;
energizing the pair of electrodes to generate a plasma within the treatment chamber from the process gas; and
directing a flow of the process gas and the plasma through a porous portion of each of the electrodes from a location outside the processing region to a pair of locations inside the processing region each defined between one of the electrodes and the substrate.

15. The method of claim 14 further comprising:
supporting the substrate between the pair of electrodes with a substrate holder; and
cooling the substrate holder and the substrate while exposed to the plasma.

16. The method of claim 14 wherein the porous portion of each of the electrodes is a perforated panel between the location outside the processing region and one of the locations inside the processing region, and directing the flow of the process gas and the plasma through the electrodes further comprises:
transmitting the flow of the process gas and the plasma through the perforated panel in each of the electrodes.

17. A method for removing thin attached polymer areas projecting from a polymer substrate, comprising:
supplying a process gas to a treatment chamber holding the polymer substrate, the process gas including a gas mixture containing oxygen and nitrogen trifluoride, and nitrogen trifluoride comprising less than or equal to about 10 percent by volume of the gas mixture;
generating a plasma from the process gas; and
exposing the polymer substrate to the plasma for a time effective to remove the thin attached polymer areas.

18. The method of claim 17 wherein generating the plasma further comprises:
transferring power to the process gas in a range of about 4000 watts to about 8000 watts at 40 kHz.

19. The method of claim 17 further comprising:
heating the polymer substrate to a process temperature above ambient temperature.

20. The method of claim 19 wherein heating the polymer substrate further comprises:
heating the polymer substrate to a process temperature in the range of about 30° C. to about 90° C.

21. The method of claim 19 wherein heating the polymer substrate further comprises:
supporting the polymer substrate in thermal contact with a substrate holder; and
cooling the substrate holder with a coolant flow to remove heat transferred from the plasma to the polymer substrate.

22. The method of claim 17 wherein generating the plasma further comprises:
positioning the polymer substrate in a processing region defined between a pair of electrodes; and
transferring the plasma and the process gas through a perforated panel in each of the pair of electrodes to the processing region.

23. The method of claim 22 further comprising:
cooling the electrodes with a coolant flow to reduce heat transferred from the electrodes to the polymer substrate.

24. The method of claim 17 wherein the gas mixture comprises about 5 percent by volume to about 10 percent by volume of nitrogen trifluoride and the balance oxygen.

25. The method of claim 17 wherein the thin attached polymer areas leave a residue on the polymer substrate after being exposing to the plasma, and further comprising:
changing the gas mixture such that nitrogen trifluoride comprises greater than or equal to about 90 percent by volume of the process gas; and
exposing the polymer substrate to the plasma for a time effective to remove the residue.

26. The method of claim 25 wherein the gas mixture comprises about 90 percent by volume to about 95 percent by volume of nitrogen trifluoride and the balance oxygen.

27. The method of claim 25 wherein the gas mixture is changed without extinguishing the plasma.
